(19) United States
(12) Patent Application Publication
(10) Pub. No.: US 2019/0222183 A1
(43) Pub. Date: Jul. 18, 2019

(54) DIFFERENTIAL HARD-SWITCHING RADIO FREQUENCY (RF) POWER AMPLIFIER

(71) Applicant: QUALCOMM Incorporated, San Diego, CA (US)

(72) Inventor: Chi-Fung KWOK, London (GB)

(21) Appl. No.: 15/872,528

(22) Filed: Jan. 16, 2018

(51) Int. Cl. H03F 3/217; H04B 1/44; H03F 3/195; H03F 3/45

(52) U.S. Cl. CPC H03F 3/2176; H04B 1/44; H03F 3/195; H03F 3/45071; H03F 2200/267; H03F 2200/09; H03F 2200/171; H03F 2200/378; H03F 2200/451

(57) ABSTRACT

A radio frequency (RF) front-end (RFFE) may include a differential hard-switching RF power amplifier. The RFFE may also include a ground bounce circuit coupled to the differential hard-switching RF power amplifier.

### BACKGROUND

### Field

The present disclosure relates generally to wireless communication systems and, more specifically, to a differential hard-switching radio frequency (RF) power amplifier.

### Background

A wireless device (e.g., a cellular phone or a smartphone) in a wireless communication system may include a radio frequency (RF) transceiver for transmitting and receiving data for two-way communication. A mobile RF transceiver may include a transmit section for transmitting data and a receive section for receiving data. For transmitting data, the transmit section may modulate an RF carrier signal with data to obtain a modulated RF signal, amplify the modulated RF signal to obtain an amplified RF signal having the proper output power level, and transmit the amplified RF signal via an antenna to a base station. For receiving data, the receive section may obtain a received RF signal via the antenna. The receive section may amplify and process the received RF signal to recover data sent by a base station.

In a mobile RF transceiver, a communication signal is amplified and transmitted by a transmit section. The transmit section may include one or more circuits for amplifying and transmitting the communication signal. The amplifier circuits may include one or more amplifier stages that may have one or more driver stages and one or more power amplifier stages. A power amplifier may include one or more stages including, for example, driver stages, power amplifier stages, or other components, that can be configured to amplify a communication signal on one or more frequencies, in one or more frequency bands, and at one or more power levels.

Highly efficient power amplifiers are generally configured for hard-switching operation. Unfortunately, hard-switching operation within a power amplifier results in out-of-band harmonics. The out-of-band harmonics may be removed by an external filter. Unfortunately, using an external filter for removing out-of-band harmonics increases a bill-of-material (BOM) cost and causes the power amplifier to consume additional board area, which is not desirable in many applications, including low cost Internet-of-Things (IoT) applications.

### SUMMARY

A radio frequency (RF) front-end (RFFE) may include a differential hard-switching RF power amplifier. The RFFE may also include a ground bounce circuit coupled to the differential hard-switching RF power amplifier.

A method for harmonic rejection within a differential hard-switching radio frequency (RF) power amplifier may include tuning an adjustable capacitor bank to resonate with an inductance of a ground interconnect and an inductance of a direct current interconnect. The ground interconnect coupled between the adjustable capacitor bank and a ground rail, and the direct current interconnect coupled between the differential hard-switching RF power amplifier and the ground rail. Tuning the capacitor bank to resonate with the inductance of the ground interconnect and the direct current interconnect reduce a voltage ground bounce of an RF front-end (RFFE) module including the differential hard-switching RF power amplifier.

A radio frequency (RF) front-end (RFFE) may include a differential hard-switching RF power amplifier. The RFFE may also include means for rejecting out-of-band harmonics generated by hard-switching operation of the differential hard-switching RF power amplifier.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 shows a wireless device communicating with a wireless system.

FIG. 2 shows a block diagram of the wireless device in FIG. 1.

FIG. 3 is a schematic diagram illustrating a radio frequency (RF) front-end (RFFE) module, including a fully integrated differential, hard-switching RF power amplifier with harmonic rejection, according to aspects of the present disclosure.

FIGS. 4A and 4B illustrate equivalence models of the on-chip ground bounce circuit of FIG. 3, according to aspects of the present disclosure.

FIG. 5 is a schematic diagram illustrating an RF front-end (RFFE) module, including duty cycle control for increasing harmonic rejection, according to aspects of the present disclosure.

FIG. 6 is a flow diagram illustrating a method for harmonic rejection from a differential hard-switching RF power amplifier within an RFFE module, in accordance with aspects of the present disclosure.

FIG. 7 is a block diagram showing an exemplary wireless communication system in which an aspect of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Designing mobile radio frequency (RF) chips (e.g., mobile RF transceivers) becomes complex at deep sub-micron process nodes due to cost and power consumption considerations. A wireless device (e.g., a cellular phone or a smartphone) in a wireless communication system may include a mobile RF transceiver for transmitting and receiving data for two-way communication. A mobile RF transceiver may include a transmit section for transmitting data and a receive section for receiving data. For transmitting data, the transmit section modulates an RF carrier signal with data to obtain a modulated RF signal. The transmit section amplifies the modulated RF signal to obtain an amplified RF signal having the proper output power level and transmits the amplified RF signal via an antenna to a base station. For receiving data, the receive section obtains a received RF signal via the antenna and amplifies and processes the received RF signal to recover data sent by a base station.

In a mobile RF transceiver, the transmit section is used for amplifying and transmitting a communication signal. The transmit section may include one or more circuits for amplifying and transmitting the communication signal. The amplifier circuits may include one or more amplifier stages that may have one or more driver stages and one or more power amplifier stages. A power amplifier may include one or more stages including, for example, driver stages, amplifier stages, or other components. The stages of the power amplifier are configured to amplify the communication signal on one or more frequencies, in one or more frequency bands, and at one or more power levels for supporting a mobile RF transceiver.

Configurations described in this specification may be used in many wireless communication systems. One particular application is Internet-of-Things. A successful Internet-of-Things (IoT) application generally involves a highly efficient mobile RF transceiver that is both low cost and of a small form factor for RF communication. The design of IoT applications, however, is complicated by the FCC, which specifies a maximum of −41 dBm (decibel-milliwatts)/MHz (megahertz) emission specification for RF transmitters. Meeting the FCC emission specification limit generally involves using an external filter, which increases cost as well as the form factor of an IoT transmitter. An efficiency of the IoT transmitter may be improved with a highly efficient power amplifier (PA).

Highly efficient power amplifiers are generally configured for hard-switching operation. Hard-switching operation may involve some overlap between voltage and current when switching a transistor ON/OFF. For example, the hard-switching operation may be applied to a metal oxide field effect transistor (MOSFET). Power amplifier manufacturers desire techniques for further reducing the voltage/current overlap during hard-switching operation. For example, soft-switching operation solves the problem by allowing the voltage/current to fall to zero (rather than just a minimum) before the MOSFET is turned on or off. Soft switching may eliminate the voltage/current overlap when switching a MOSFET ON/OFF; however, soft-switching may reduce the output power and efficiency of a power amplifier.

A hard-switching power amplifier is desirable for achieving a high output power as well as improved efficiency. For example, hard-switch power amplifiers (e.g., class/inverse class D, E, F rather than class A, AB, B, C) are desired for certain applications for providing higher output power and better efficiency. Unfortunately, hard-switching operation within power amplifiers results in out-of-band harmonics. The out-of-band harmonics may be removed with an external filter. Using an external filter to remove out-of-band harmonics, however, increases a bill-of-material (BOM) cost. This external filter also causes the power amplifier to consume additional board area, which is not desirable.

Conventional IoT applications use a single-ended power amplifier for meeting the FCC maximum emission specification. Unfortunately, single-ended power amplifiers have a limited maximum output power. In addition, single-ended power amplifiers are likely to introduce more power amplifier-voltage controlled oscillator (PA-VCO) pulling compared with a differential power amplifier. PA-VCO pulling affects an operating frequency of a voltage controlled oscillator by affecting the load impedance of the oscillator and introducing the impedance at the load of the oscillator.

Aspects of the present disclosure include a hard-switching RF power amplifier for reducing out-of-band harmonics produced by hard-switching operation. An external filter is eliminated, which results in a smaller form factor and a reduced cost of the hard-switching power amplifier. A fully integrated, differential hard-switching PA may produce high output power with good power amplifier efficiency. The differential hard-switching PA may use an integrated on-chip transmit/receive (TR) switch.

According to aspects of the present disclosure, an RF front-end may include a differential PA, in which a receiver may benefit from additional gain produced by the RF front-end. The RF front-end may also include a filter, which may be on-chip, and an transmit/receive switch, which may be integrated with the RF front-end. The RF front-end may also include a ground bounce elimination circuit for reducing second harmonic emissions produced by the differential, hard-switching power amplifier. In addition, a duty cycle of a local oscillator (LO) input may cancel second-order harmonics from the differential, hard-switching power amplifier. The duty cycle (e.g., a 50% duty) may be varied for canceling second-order harmonics from the differential, hard-switching power amplifier.

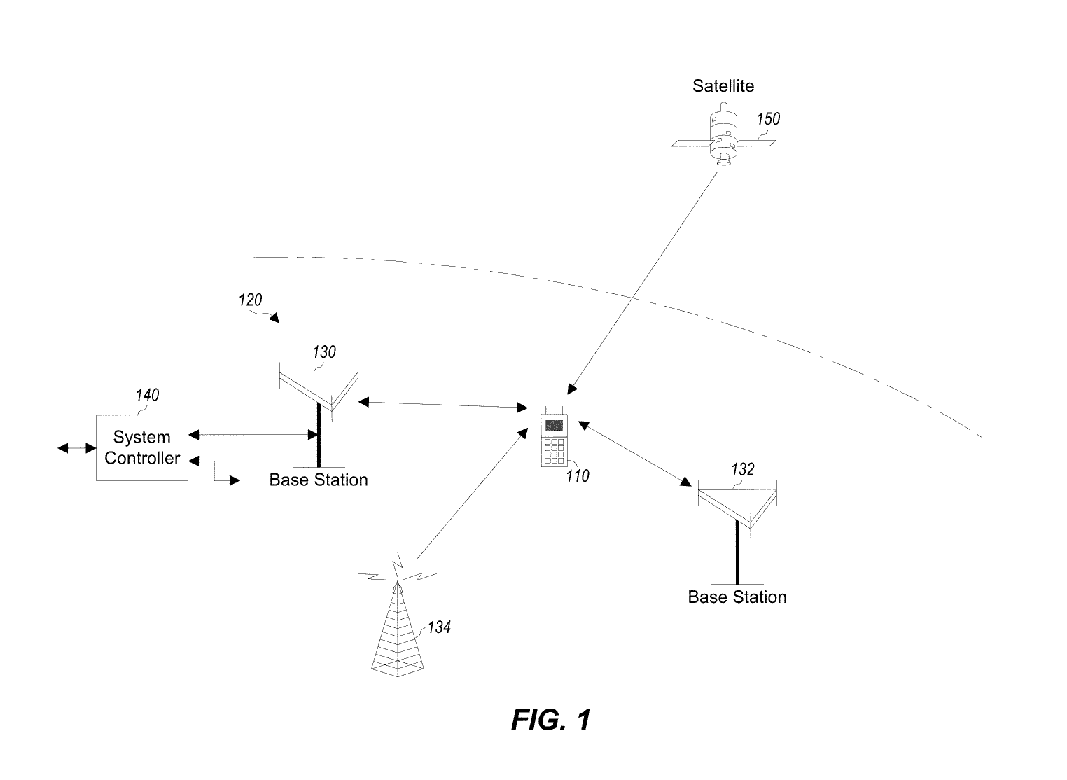

FIG. 1 shows a wireless device 110 communicating with a wireless communication system 120, including a fully integrated differential hard-switching radio frequency (RF) power amplifier with harmonic rejection, according to aspects of the present disclosure. The wireless communication system 120 may be a 5G system, a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), time division synchronous CDMA (TD-SCDMA), CDMA2000, or some other version of CDMA. For simplicity, FIG. 1 shows the wireless communication system 120 including two base stations 130 and 132 and one system controller 140. In general, a wireless system may include any number of base stations and any number of network entities.

A wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. For example, the wireless device 110 may support Bluetooth Low Energy (BLE)/BT (Bluetooth) with a low energy/high efficiency power amplifier having a small form factor of a low cost.

The wireless device 110 may be capable of communicating with the wireless communication system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communication such as 5G, LTE, CDMA2000, WCDMA, TD-SCDMA, GSM, 802.11, BLE/BT, etc. The wireless device 110 may also support carrier aggregation, which is operation on multiple carriers.

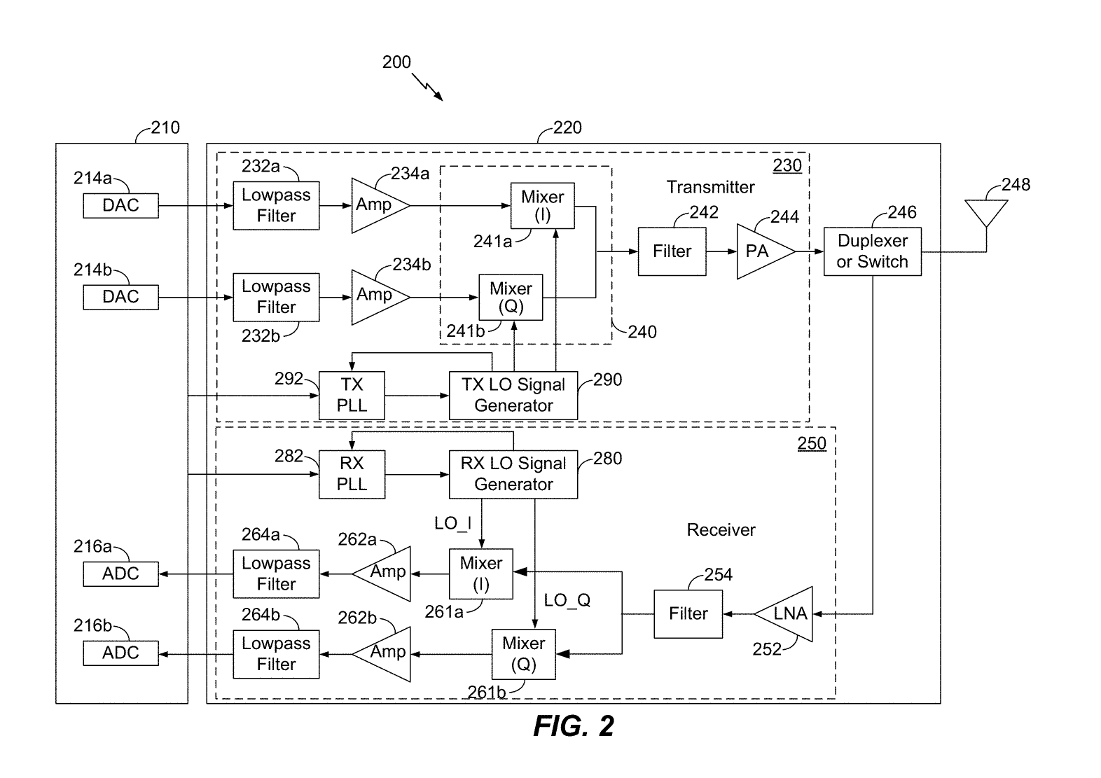

FIG. 2 shows a block diagram of an exemplary design of a wireless device 200, such as the wireless device 110 shown in FIG. 1, including a fully integrated differential hard-switching radio frequency (RF) power amplifier with harmonic rejection, according to aspects of the present disclosure. FIG. 2 shows an example of a mobile RF transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 1. Furthermore, other circuit blocks not shown in FIG. 2 may also be used to condition the signals in the transmitter 230 and receiver 250. Unless otherwise noted, any signal in FIG. 2, or any other figure in the drawings, may be either single-ended or differential. Some circuit blocks in FIG. 2 may also be omitted.

In the example shown in FIG. 2, the wireless device 200 generally includes the mobile RF transceiver 220 and a data processor 210. The data processor 210 may include a memory (not shown) to store data and program codes, and may generally include analog and digital processing elements. The mobile RF transceiver 220 may include the transmitter 230 and receiver 250 that support bi-directional communication. In general, the wireless device 200 may include any number of transmitters and/or receivers for any number of communication systems and frequency bands. All or a portion of the mobile RF transceiver 220 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages, for example, from radio frequency to an intermediate frequency (IF) in one stage, and then, from intermediate frequency to baseband in another stage for a receiver. In the direct-conversion architecture, a signal is frequency converted between radio frequency and baseband in one stage. The super-heterodyne and direct-conversion architectures may use different circuit blocks and/or have different requirements. In the example shown in FIG. 2, the transmitter 230 and the receiver 250 are implemented with the direct-conversion architecture.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog-converters (DACs) 214a and 214b for converting digital signals generated by the data processor 210 into the in-phase (I) and quadrature (Q) analog output signals (e.g., I and Q output currents) for further processing.

Within the transmitter 230, lowpass filters 232a and 232b filter the in-phase (I) and quadrature (Q) analog transmit signals, respectively, to remove undesired images caused by the prior digital-to-analog conversion. Amplifiers 234a and 234b (Amp) amplify the signals from lowpass filters 232a and 232b, respectively, and provide in-phase (I) and quadrature (Q) baseband signals. Upconverters 240 include an in-phase upconverter 241a and a quadrature upconverter 241b that upconverter the in-phase (I) and quadrature (Q) baseband signals with in-phase (I) and quadrature (Q) transmit (TX) local oscillator (LO) signals from a TX LO signal generator 290 to provide upconverted signals. A filter 242 filters the upconverted signals to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by lowpass filters 264a and 264b to obtain in-phase (I) and quadrature (Q) analog input signals, which are provided to the data processor 210. In the exemplary configuration shown, the data processor 210 includes analog-to-digital-converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

The mobile RF transceiver 220 may be implemented in a small form factor and at a reduced cost for supporting an Internet-of-Things (IoT) application. The design of IoT applications, however, is complicated by the FCC, which specifies a maximum of −41 dBm (decibel-milliwatts)/MHz (megahertz) emission specification for RF transmitters, such as the transmitter 230. Meeting the FCC emission specification limit generally involves an external filter, which increases cost as well as the form factor of the transmitter 230. An efficiency of the transmitter 230 may be improved by using a highly efficient power amplifier to implement the power amplifier 244.

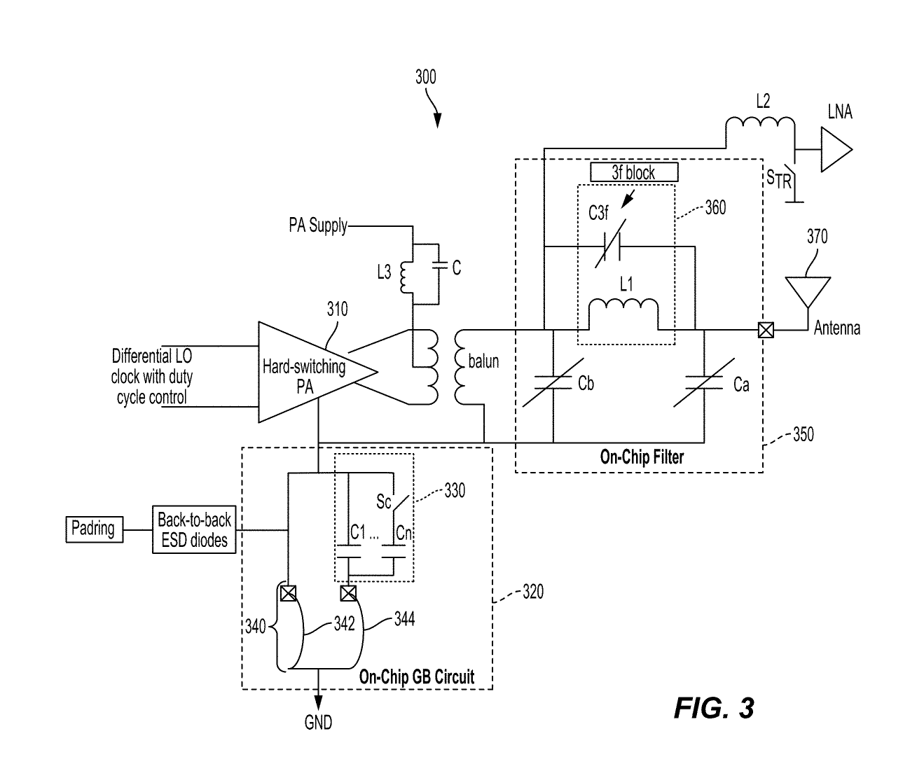

Highly efficient power amplifiers are generally configured for hard-switching operation. Hard-switching operation may involve some overlap between voltage and current when switching a transistor ON/OFF. For example, the hard-switching operation may be applied to a metal oxide field effect transistor (MOSFET). Power amplifier manufacturers desire techniques for further reducing the voltage/current overlap during hard-switching operation. For example, soft-switching operation solves the problem by allowing the voltage/current to fall to zero (rather than just a minimum) before the MOSFET is turned on or off. Soft switching may eliminate the voltage/current overlap when switching a MOSFET ON/OFF; however, soft-switching may reduce the output power and efficiency of a power amplifier. A hard-switching power amplifier is desirable for achieving a high output power as well as improved efficiency, for example, as shown in FIG. 3.

FIG. 3 is a schematic diagram illustrating an RF front-end (RFFE) module 300, including a fully integrated differential hard-switching radio frequency (RF) power amplifier with harmonic rejection, according to aspects of the present disclosure. Representatively, a hard-switching RF power amplifier 310 is shown in differential configuration. By contrast, conventional IoT applications use a single-ended power amplifier for meeting the FCC maximum emission specification. Unfortunately, single-ended power amplifiers have a limited maximum output power. In addition, single-ended power amplifiers are likely to introduce more power amplifier-voltage controlled oscillator (PA-VCO) pulling on chip compared with a differential power amplifier.

In this example, the RFFE module 300 includes a single-ended antenna 370. As a result, a balun (e.g., a balun filter) is coupled to differential outputs of the hard-switching RF power amplifier 310 to convert a differential output signal to a single-ended output signal for transmitting using the single-ended antenna 370. The balun is coupled to a power rail (PA supply) through an inductor L3 and a capacitor C. While the hard-switching RF power amplifier 310 provides an increased output power (e.g., +10 dBm) as well as improved efficiency, hard-switching operation within power amplifiers results in out-of-band harmonics. Conventionally, these out-of-band harmonics are removed with an external (e.g., off-chip) filter. Using an external filter for removing out-of-band harmonics, however, increases a bill-of-material (BOM) cost. This external filter also causes the power amplifier to consume additional board area.

According to aspects of the present disclosure, the RFFE module 300 includes an integrated transmit/receive switch S_{TR}. The integrated transmit/receive switch S_{TR} is coupled to an inductor L2 and a low noise amplifier (LNA). When transmitting data, the integrated transmit/receive switch S_{TR} is on. When receiving data, the integrated transmit/receive switch S_{TR} is off Including the integrated transmit/receive switch S_{TR} on-chip avoids using an external switch, which would increase the form factor of the RFFE module 300. As a result, a form factor of the RFFE module 300 is also reduced by the integrated transmit/receive switch S_{TR} for supporting IoT applications that communicate using, for example, Bluetooth Low Energy (BLE)/BT (Bluetooth).

A form factor of the RFFE module 300 is further reduced by including an on-chip filter 350 for eliminating third order, fourth order, and fifth order harmonics in the RFFE module 300. In this configuration, the on-chip filter 350 (e.g., an on-chip harmonic filter block) includes a third-order harmonic filter block 360 (e.g., 3f block) coupled between the balun and the single-ended antenna 370. The third-order harmonic filter block 360 includes a capacitor C3f in parallel with an output series inductor L1. Third order harmonics are attenuated by the output series inductor L1 and the parallel capacitance C3f. The on-chip filter 350 also includes capacitors Ca and Cb for providing matching within the on-chip filter 350 for attenuating any third, fourth, or fifth order harmonics. The inductor L1 also forms a low-pass filter with capacitors Ca and Cb, which attenuates harmonic emission for frequencies above a fundamental frequency. It is noted that failing to attenuate the third order, fourth order, or fifth order harmonics likely prevents the RFFE module 300 from meeting the FCC maximum emission specification noted above.

In the configuration shown in FIG. 3, the RFFE module 300 includes the balun for converting the differential output signals of the hard-switching RF power amplifier 310 to a single-ended output signal for transmitting data using the single-ended antenna 370. A ground of the balun is coupled to a ground pin of the hard-switching RF power amplifier 310 in this balun ground configuration. Unfortunately, a finite coupling capacitance of the balun as well as an asymmetry of the balun may induce a common mode signal. This common mode signal flows through the single-ended antenna 370 and returns to the hard-switching RF power amplifier 310, resulting in a high second order harmonic emission.

In operation, the common mode signal results in a high second order harmonic emission due to an increased ground voltage caused by a ground bounce phenomenon. The ground bounce phenomenon refers to an undesirable condition in which a voltage of a ground plane is increased from zero volts (e.g., 0V—an ideal ground) to a value greater than 0V, which may be due to inductance and/or capacitance connected to the ground plane. In this example, the common mode signal returns to the ground pin of the hard-switching PA, which results in an increased voltage of the ground rail GND, when directly coupled to the ground pin of the hard-switching PA.

One solution for avoiding ground bounce is separating the balun ground from the ground pin of the hard-switching RF power amplifier 310. This ground configuration may prevent a common mode signal from flowing through the antenna and returning to the hard-switching RF power amplifier 310, thus, eliminating the second order harmonic emission by negating the common mode signal. Unfortunately, separating the balun ground from the ground pin of the hard-switching RF power amplifier 310 may prevent the RFFE module 300 from meeting the FCC maximum emission specification. In one aspects of the present disclosure, compliance with the FCC maximum emission specification is achieved by shorting the balun ground to the ground pin of the hard-switching RF power amplifier 310 for coupling to an ideal ground (e.g., 0V) that is isolated from the ground bounce phenomenon.

According to aspects of the present disclosure, the RFFE module 300 includes an on-chip ground bounce circuit 320 coupled to a ground pin of the hard-switching RF power amplifier 310 and the balun ground. In this aspect of the present disclosure, the on-chip ground bounce circuit 320 is configured for shorting the balun ground to the ground pin of the hard-switching RF power amplifier 310. The balun ground and ground pin are shorted to an ideal ground (e.g., 0V) provided by a ground rail GND that is isolated from the ground bounce phenomenon.

In this aspects of the present disclosure, the on-chip ground bounce circuit 320 relies on resonating inductors and capacitors for preventing an induced common mode signal from raising a voltage of the ground rail GND. As described in further detail below, the capacitors may be provided in a capacitor bank 330. In addition, the inductors refer to wire bonds 340 (e.g., a first interconnect 342 and a second interconnect 344), which are modeled as inductors, based on a wire inductance (e.g., a parasitic inductance), rather than conventional multi-turn inductors. In operation, the on-chip ground bounce circuit 320 isolates the ground rail GND, such that a voltage of the ground rail GND is fixed at 0V (e.g., an ideal ground).

In this configuration, the on-chip ground bounce circuit 320 includes a capacitor bank 330 having capacitors (e.g., C1, . . . , Cn) coupled together with a capacitor switch Sc, which may include a set of capacitor switches Sc. In this example, the capacitors are tunable and configured with a predetermined quality (Q)-factor (e.g., <10) for avoiding excess voltage swing between inductors (e.g., wire bonds 340) and the capacitors (e.g., C1, . . . , Cn) of the on-chip ground bound circuit 320. The on-chip ground bounce circuit 320 also includes the wire bonds 340 (e.g., the first interconnect 342 and the second interconnect 344) coupled to the ground rail GND that are modeled as inductors (e.g., a parasitic inductance). The first interconnect 342 may be referred to as a direct current (DC) ground wire-bond coupled between the ground pin of the hard-switching RF power amplifier 310, the balun ground and the ground rail GND. In addition, the second interconnect 344 may be referred to as a resonant ground wire-bond coupled between the capacitor bank 330 and the ground rail GND.

In operation, the capacitor bank 330 is tuned to resonate (e.g., at 2.44 GHz) with a parasitic inductance of the first interconnect 342 and the second interconnect 344 to short the ground pin of the hard-switching RF power amplifier 310 and the balun ground to the ground rail GND. Shorting the ground pin of the hard-switching RF power amplifier 310 and the balun ground to the ground rail GND helps reduce second order harmonics by blocking the ground rail GND from a common mode signal induced by the coupling capacitance of the balun as well as the asymmetry of the balun. In particular, LC resonating of the on-chip ground bounce circuit 320 prevents forming of the common mode signal so that the ground rail GND remains fixed at 0V (e.g., an ideal ground). Shorting the ground pin of the hard-switching PA as well as the balun ground to the ideal ground provided by the ground rail GND significantly reduces second order harmonics, which enables compliance with FCC maximum emission specification.

In this configuration, back-to-back electrostatic discharge (ESD) diodes and a pad-ring are also coupled to the first interconnect 342. The pad-ring and diodes (e.g., ESD diodes) may be used to protect the RFFE module 300 during an ESD event. The pad-ring and ESD diodes support compatibility between the RFFE module 300 and an ESD protection structure of any chip design. The hard-switching RF power amplifier 310 may be incorporated into a power amplifier such as, for example, the power amplifier 244, as shown in FIG. 2.

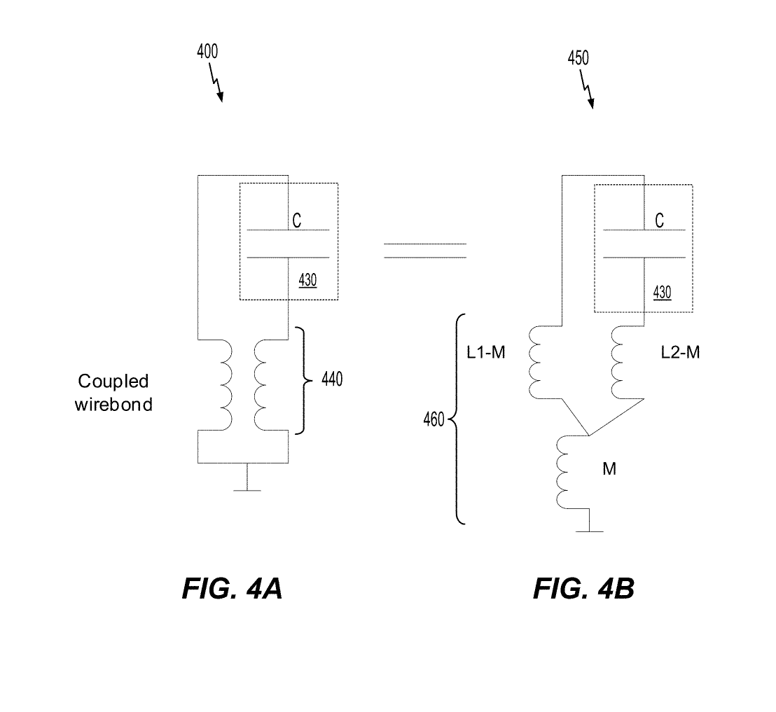

FIGS. 4A and 4B illustrate equivalence models of the on-chip ground bounce circuit of FIG. 3, according to aspects of the present disclosure. Equivalence models of the on-chip ground bounce circuit in FIGS. 4A and 4B presume mutual coupling between the first interconnect 342 and the second interconnect 344. FIG. 4A illustrates a first equivalence model 400 of the on-chip ground bounce circuit 320, with mutual coupling between the first interconnect 342 and the second interconnect 344. Mutual coupling between the first interconnect 342 and the second interconnect 344 is modeled as a transformer 440 shown FIG. 4A.

FIG. 4B illustrates a second equivalence model 450 of the on-chip ground bounce circuit 320, with mutual coupling between the first interconnect 342 and the second interconnect 344. In this example, M represents a coupling factor or an amount of mutual coupling between the first interconnect 342 and the second interconnect 344. The first equivalence model 400 and the second equivalence model 450 assume mutual coupling (e.g., M>0). The second equivalence model 450 illustrates a circuit diagram representation 460 of the mutual coupling between the first interconnect 342 and the second interconnect 344.

When there is no mutual inductance (M=0), the first interconnect 342 and the second interconnect 344 are represented as inductors L1 and L2, respectively, as ideal inductances unaffected by mutual inductance. These ideal inductances L1 and L2, however, are affected by the coupling factor M when M is greater than zero (e.g., M>0). In the second equivalence model 450, the first interconnect 342 and the second interconnect 344 are represented by inductors L1-M and L2-M, coupled in parallel, with an inductor M, coupled in series. The circuit diagram representation may be used to tune the capacitor bank 430 for resonating a capacitance C of the capacitor bank 430 and inductances L1-M and L2-M of the first interconnect 342 and the second interconnect 344, respectively, as well as a coupling factor M inductance.

It should be recognized that a coupling factor between the first interconnect 342 and the second interconnect 344 should be sufficiently small for successful operation of the on-chip ground bounce 320. In addition, an operating frequency for suppressing ground bounce is detected when a “zero” is formed by resonance between the L2-M inductor and a capacitance of the capacitor bank 330. A notch is also created by the L1-M inductor and the capacitance of the capacitor bank 330. The notch frequency is computed as follow:

$${f}_{open} = {f}_{0} * \sqrt{\frac{1}{( 1 + C * ( L 1 + L 2 - 2 * M )}} \qquad ( 1 )$$

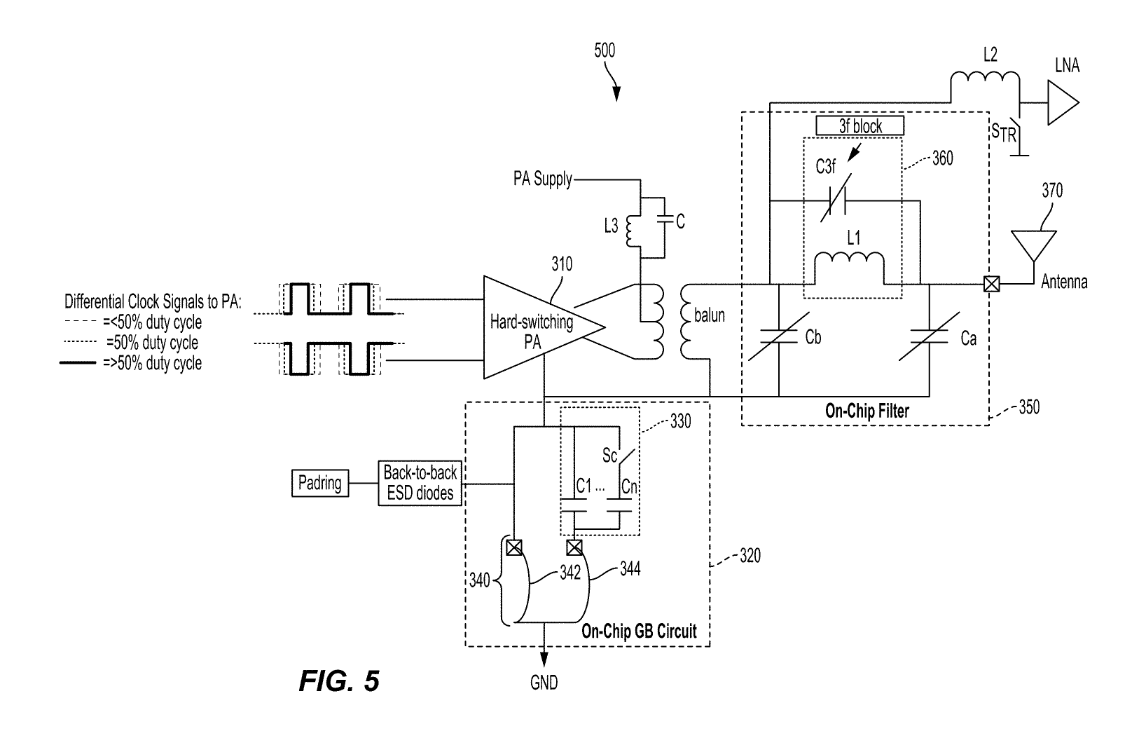

The capacitor bank 430 capacitance C is tuned to resonate with the inductance L1 of the first interconnect 342 and the inductance L2 of the second interconnect 344 for shorting the ground pin of the hard-switching RF power amplifier 310 and the balun ground to the ground rail, as shown in FIG. 3. Shorting the ground pin of the hard-switching RF power amplifier 310 to the balun ground and to the ground rail substantially reduces a common mode signal. The common mode signal causes a high second order harmonic emission due to an increased ground voltage of the ground rail caused by the ground bounce phenomenon. Out-of-band harmonics generated by hard-switching operation within the hard-switching RF power amplifier 310 may be further reduced, as shown in FIG. 5.

FIG. 5 is a schematic diagram illustrating an RF front-end (RFFE) module, including duty cycle control for increasing out-of-band harmonic rejection, according to aspects of the present disclosure. An RFFE module 500 is shown using similar components and similar reference numerals to the RFFE module 300 shown in FIG. 3. In the configuration shown in FIG. 3, the RFFE module 300 may suffer from additional second order out-of-band harmonics due to device mismatch within the differential, hard-switching RF power amplifier 310.

In the example shown in FIG. 5, device mismatch of the hard-switching RF power amplifier 310 is mitigated by adjusting a duty cycle of input differential clock signals to balance/cancel out device mismatch. Device mismatches can be balanced because in a differential amplifier, the average switch resistance depends on the switch properties as well as the duty cycle of the clock. For example, when one of the two differential switches experience larger resistance due to mismatch, a pulse width of the clock may be modified so that an average resistance during a clock period is equalized.

In this aspect of the present disclosure, the RFFE module 500 varies the input differential clock's duty cycle for canceling device mismatch of the differential, hard-switching RF power amplifier 310. In this example, a fifty percent (50%) duty cycle is used as the input differential clock's duty cycle for reducing device mismatch of the differential, hard-switching RF power amplifier 310. It should be noted that the 50% duty cycle is exemplary, as other duty cycles are also possible according to aspects of the present disclosure. That is, the duty cycle adjustment may be a design parameter that is varied to provide a desired reduction level of device mismatch for mitigating second-order out-of-band harmonics.

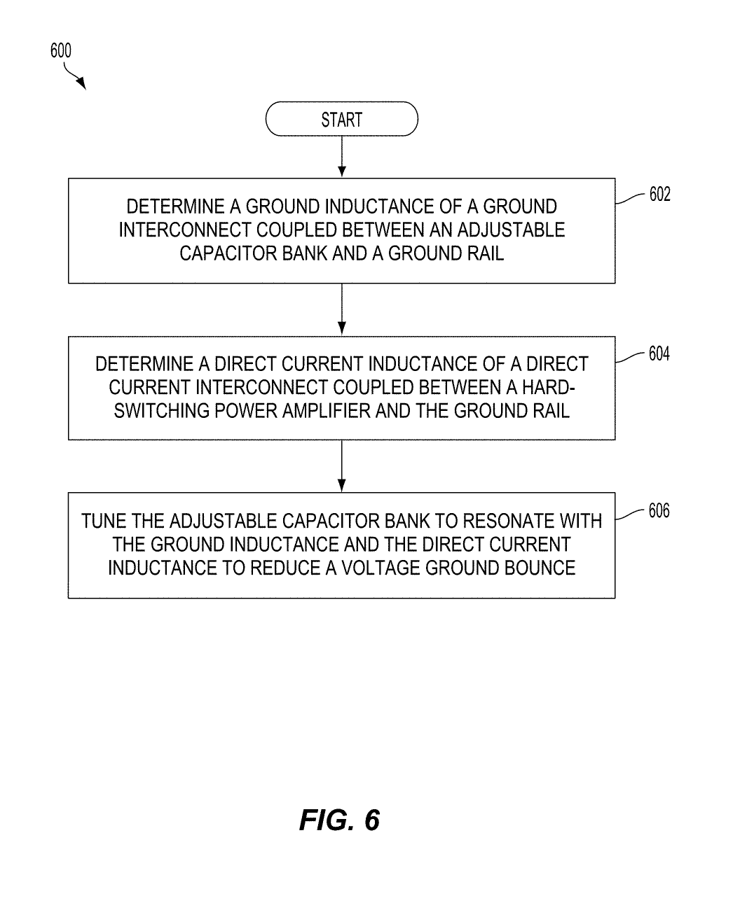

Second order harmonic emissions due to device mismatch of the differential, hard-switching RF power amplifier 310 are, therefore, reduced by varying the duty cycle of the input differential clock signal. In this example, the inductance of the first interconnect 342 and the second interconnect 344 resonate with the capacitance C of the capacitor bank 330 at a predetermined frequency (e.g., 2.44 GHz) to reduce second order harmonic emissions from hard-switching operation of the differential, hard-switching RF power amplifier 310. The on-chip ground bounce circuit 320 as well as the duty cycle control enable a fully integrated differential hard-switching RF power amplifier with harmonic rejection for IoT applications according to aspects of the present disclosure. A method of harmonic rejection for the differential, hard-switching RF power amplifier 310 is shown in FIG. 6.

FIG. 6 is a flow diagram illustrating a method 600 for harmonic rejection from a differential, hard-switching RF power amplifier within an RFFE module, in accordance with aspects of the present disclosure. The blocks in the method 600 can be performed in or out of the order shown, and in some aspects, can be performed at least in part in parallel.

At block 602, a ground inductance of a ground interconnect coupled between an adjustable capacitor bank and a ground rail is determined. For example, as shown in FIG. 3, an inductance of the second interconnect 344 is determined. At block 604, a direct current inductance of a direct current interconnect coupled between a hard-switching RF power amplifier and the ground rail is determined. For example, as shown in FIG. 3, an inductance of the first interconnect 342 is determined. The combined inductance (e.g., parasitic inductance) of the first interconnect 342 and the second interconnect 344 is fixed, but will vary depending on whether the first interconnect 342 and the second interconnect 344 are implemented using wire bonds or back-end-of-line (BEOL) interconnects.

Referring again to FIG. 6, at block 606, the adjustable capacitor bank is tuned to resonate with the ground inductance and the direct current inductance to reduce a voltage ground bounce. For example, as shown in FIG. 3, the capacitor bank 330 is tuned to resonate with an inductance of the first interconnect 342 and the second interconnect 344 to short the ground pin of the differential, hard-switching RF power amplifier 310 and the balun ground to the ground rail. Shorting the ground pin of the hard-switching RF power amplifier 310 and the balun ground to the ground rail helps reduces second order harmonics produced by the hard-switching RF power amplifier 310.

Conventional IoT applications use a single-ended power amplifier for meeting the FCC maximum emission specification. Unfortunately, single-ended power amplifiers have a limited maximum output power. Aspects of the present disclosure include a hard-switching RF power amplifier for reducing out-of-band harmonics produced by hard-switching operation. An on-chip filter results in a smaller form factor and a reduced cost of the hard-switching power amplifier. A fully integrated, differential hard-switching RF power amplifier may produce high output power with good power amplifier efficiency. The differential hard-switching PA may use a fully integrated transmit/receive (TR) switch. In addition, a duty cycle of a local oscillator (LO) input may further reduce second-order harmonics from the differential, hard-switching power amplifier.

According to a further aspect of the present disclosure, an RFFE module including a differential, hard-switching RF power amplifier is described. The RFFE includes means for rejecting out-of-band harmonics generated by hard-switching operation of the differential hard-switching RF power amplifier. The means for rejecting may, for example, include the on-chip ground bounce circuit 320, as shown in FIGS. 3 and 5. In another aspect, the aforementioned means may be any module, or any apparatus configured to perform the functions recited by the aforementioned means.

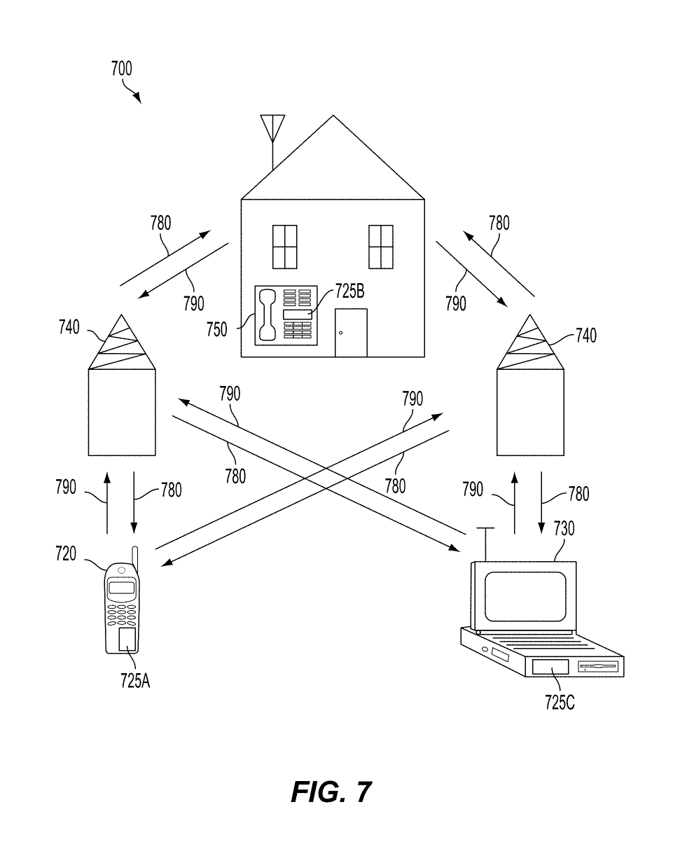

FIG. 7 is a block diagram showing an exemplary wireless communication system 700 in which an aspect of the disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include IC devices 725A, 725C, and 725B that include the disclosed differential, hard-switching RF power amplifier. It will be recognized that other devices may also include the disclosed differential, hard-switching RF power amplifier, such as the base stations, user equipment, and network equipment. FIG. 7 shows forward link signals 780 from the base station 740 to the remote units 720, 730, and 750 and reverse link signals 790 from the remote units 720, 730, and 750 to base station 740.

In FIG. 7, remote unit 720 is shown as a mobile telephone, remote unit 730 is shown as a portable computer, and remote unit 750 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 7 illustrates remote units according to the aspects of the disclosure, the disclosure is not limited to these exemplary illustrated units. Aspects of the disclosure may be suitably employed in many devices, which include the disclosed differential, hard-switching RF power amplifier.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communication networks and/or communication technologies. The apparatuses, methods, and systems disclosed herein may also be implemented digitally and differentially, among others. The various components illustrated in the figures may be implemented as, for example, but not limited to, software and/or firmware on a processor, ASIC/FPGA/DSP, or dedicated hardware. In addition, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

Although the present disclosure provides certain example aspects and applications, other aspects that are apparent to t hose of ordinary skill in the art, including aspects, which do not provide all of the features and advantages set forth herein, are also within the scope of this disclosure. For example, the apparatuses, methods, and systems described herein may be performed digitally and differentially, among others. Accordingly, the scope of the present disclosure is intended to be defined only by reference to the appended claims.

What is claimed is:

1. A radio frequency (RF) front-end (RFFE), comprising:
a differential hard-switching RF power amplifier; and
a ground bounce circuit coupled to the differential hard-switching RF power amplifier.

2. The RFFE of claim 1, further comprising:
a balun filter coupled to the differential hard-switching RF power amplifier; and
a filter coupling an antenna to the balun filter.

3. The RFFE of claim 2, further comprising a transmit/receive switch coupled to the antenna through the filter.

4. The RFFE of claim 3, in which the transmit/receive switch comprises an integrated on-chip transmit/receive switch.

5. The RFFE of claim 2, in which the filter comprises an on-chip harmonic filter block.

6. The RFFE of claim 2, in which the filter comprises capacitors configured to provide matching within the filter to attenuate out-of-band harmonic frequencies.

7. The RFFE of claim 1, in which the ground bounce circuit comprises:
a tunable capacitance coupled to the differential hard-switching RF power amplifier;
a ground interconnect coupled between the tunable capacitance and a ground rail; and
a direct current interconnect coupled between the differential hard-switching RF power amplifier and the ground rail.

8. The RFFE of claim 7, in which the tunable capacitance comprises an on-chip adjustable capacitor bank.

9. The RFFE of claim 7, in which the ground interconnect and the direct current interconnect comprise wire bonds.

10. The RFFE of claim 7, in which the ground interconnect and the direct current interconnect comprise back-end-of-line (BEOL) interconnects.

11. A method for harmonic rejection within a differential hard-switching radio frequency (RF) power amplifier, comprising:
tuning an adjustable capacitor bank to resonate with an inductance of a ground interconnect coupled between the adjustable capacitor bank and a ground rail and an inductance of a direct current interconnect coupled between the differential hard-switching RF power amplifier and the ground rail to reduce a voltage ground bounce of an RF front-end (RFFE) module including the differential hard-switching RF power amplifier.

12. The method of claim 11, further comprising controlling a duty cycle of an input differential clock signal of the differential hard-switching RF power amplifier to reduce second order harmonic emissions from the differential hard-switching RF power amplifier.

13. The method of claim 11, further comprising:
activating an integrated transmit/receive switch during transmitting of data by the RFFE module; and
de-activating the integrated transmit/receive switch during receiving of data by the RFFE module.

14. The method of claim 11, further comprising converting a differential output signal from the differential hard-switching RF power amplifier for a single-ended antenna of the RFFE module.

15. A radio frequency (RF) front-end (RFFE), comprising:
a differential hard-switching RF power amplifier; and
means for rejecting out-of-band harmonics generated by hard-switching operation of the differential hard-switching RF power amplifier.

16. The RFFE of claim 15, further comprising:
a balun filter coupled to the differential hard-switching RF power amplifier; and
an filter coupling an antenna to the balun filter.

17. The RFFE of claim 16, further comprising a transmit/receive switch coupled to the antenna through the filter.

18. The RFFE of claim 17, in which the transmit/receive switch comprises an integrated on-chip transmit/receive (T/R) switch.

19. The RFFE of claim 16, in which the filter comprises an on-chip harmonic filter block.

20. The RFFE of claim 16, in which the filter comprises capacitors configured to provide matching within the filter to attenuate out-of-band harmonic frequencies.
